(19) United States
(12) Patent Application Publication
(10) Pub. No.: US 2025/0393122 A1
(43) Pub. Date: Dec. 25, 2025

(54) SYSTEM AND METHOD FOR L-SHAPE DIFFERENTIAL LINE ROUTING

(71) Applicant: Harman International Industries, Incorporated, Stamford, CT (US)

(72) Inventors: Ionut-Liviu Jianu, Village Urzica, County OLT (RO); Liviu-Dumitru Craciun, Rülzheim (DE); Vlad-Alexandru Barbalata, Bucharest (RO); Paul-Alexandru Biliga-Nisipeanu, Bistrita City, Bistrita-Nasaud County (RO)

(21) Appl. No.: 19/111,720

(22) PCT Filed: Oct. 30, 2023
(86) PCT No.: PCT/US2023/078229

§ 371 Date: Mar. 13, 2025

Related U.S. Application Data
(60) Provisional application No. 63/381,881, filed on Nov. 1, 2022.

(51) Int. Cl. H05K 1/02; H05K 1/11; H05K 1/18

(52) U.S. Cl. CPC H05K 1/0298; H05K 1/115; H05K 1/181; H05K 2201/10022

(57) ABSTRACT

Systems and methods are disclosed for routing differential communication lines to different integrated circuits based on printed circuit board (PCB) unit variants. In one example, a system for routing signals comprises a location for mounting either a first resistor or a second resistor and another location for mounting either a third resistor or fourth resistor, the location for receiving either the first resistor or the second resistor being shaped such that, when populated with the first resistor, the first resistor is in a first orientation, and when populated with the second resistor, the second resistor is in a second orientation perpendicular to the first orientation.

### CROSS REFERENCE TO RELATED APPLICATIONS

The present application claims priority to U.S. Provisional Application No. 63/381,881 entitled “SYSTEM AND METHOD FOR L-SHAPE DIFFERENTIAL LINE ROUTING”, and filed on Nov. 1, 2022. The entire contents of the above-listed application are hereby incorporated by reference for all purposes

### BACKGROUND

Current solutions used to route differential communication lines to different integrated circuits may degrade signal integrity. In particular, a via mounted in front of a plurality of resistors on a printed circuit board (PCB) may be utilized to direct a signal to a path for a particular integrated circuit (IC) on one of the top layer or bottom layer or to a plurality of integrated circuits (IC). Depending on the path for a particular integrated circuit (IC), a stub, such as an unused trace section, may degrade a signal being transmitted through the communication line when vias are present and the signal path is split. Signal degradation may be reduced by mounting a pair of resistors on a PCB in a specific configuration depending on a printed circuit board unit variant

### SUMMARY

As disclosed herein, a system and method for routing differential communication lines to different integrated circuits based on printed circuit board (PCB) population variant. The proposed system may comprise a location for mounting either a first resistor or a second resistor and another location for mounting either a third resistor or fourth resistor. Once populated with the selected resistors, the system couples the populated resistors in the PCB to electrically route a differential communication line having a positive trace and a negative trace. In this way, a product line of a plurality of printed circuit board (PCB) unit variants may be produced with the same sets of traces and vias, but populated with resistors in different combinations to enable different chip positioning (e.g., top or bottom) utilizing the differential communication line.

In an example, the location for receiving either the first resistor or second resistor is shaped such that, when populated with the first resistor (and thus with the PCB in a first configuration), the first resistor is in a first orientation, and when populated with the second resistor (and thus with the circuit board in a second configuration), the second resistor is in a second orientation perpendicular to the first orientation. In an example, in each of the first and second configuration, the location includes only a single input trace and two output traces, such that one populated with only one of the first and second resistors, the completed signal lines do not have any stubs created by the remaining traces of the split branching therefrom. In this way, extraneous traces and/or vias that dead end are eliminated, thereby eliminating the antenna effect of such extraneous traces, thus improving signal quality of the differential communication line, even at very high communication speeds (e.g., in order of magnitude of hundreds of Megahertz or Gigahertz).

In an example, the location for receiving either the third or fourth resistor is shaped such that, when populated with the third resistor (and thus with the PCB in the first configuration), the third resistor is in the first orientation, and when populated with the fourth resistor (and thus with the circuit board in the second configuration), the fourth resistor is in the second orientation perpendicular to the first orientation. In an example, in each of the first and second configuration, the location includes only a single input trace, and two output traces, such that one populated with only one of the third and fourth resistors, the completed signal lines do not have any stubs branching therefrom. In this way, extraneous traces and/or vias that dead end are reduced, thereby reducing an antenna effect of such extraneous traces, thus improving signal quality of the differential communication line, even at very high communication speeds (e.g., gigahertz).

In an example, either the first resistor or the second resistor may be mounted at a designated location of a first PCB unit variant and either the first resistor or the second resistor may be mounted at a designated location of a second PCB unit variant. In this way, the angle between the first resistor and the second resistor between the first PCB unit variant and the second PCB unit variant may vary by up to 90°, such that the first resistor and the second resistor would form an L-shape if both were mounted. Similarly, either the third resistor or the fourth resistor may be mounted at a designated location of the first PCB unit variant and either the third resistor or the fourth resistor may be received at a designated location of the second PCB unit variant. In this way, the angle between the third resistor and the fourth resistor between the first PCB unit variant and the second PCB unit variant, if both were received, may vary by 90°, such that the third resistor and the fourth resistor would form an L-shape if both were mounted. The third resistor and fourth resistor are flipped vertically compared to the first resistor and second resistor.

A method utilizing the PCB configuration described above may be utilized to transmit signals via the differential communication lines. In particular, one pair of resistors may be oriented horizontally to route the signal to a first integrated circuit (IC) in the first PCB unit variant. Another pair of resistors may be oriented vertically to route the signal to a second integrated circuit (IC) in the second PCB unit variant.

It should be understood that the summary above is provided to introduce in simplified form a selection of concepts that are further described in the detailed description. It is not meant to identify key or essential features. Furthermore, the present application is not limited to implementations that solve any disadvantages noted above or in any part of this disclosure.

### BRIEF DESCRIPTION OF THE DRAWINGS

The disclosure may be better understood from reading the following description of non-limiting embodiments, with reference to the attached drawings, wherein below:

FIG. 1 shows an example of a printed circuit board (PCB) configuration wherein a plurality of resistors forms an L-shape;

FIG. 2 shows a top view of a printed circuit board (PCB) wherein a plurality of resistors forms an L-shape;

FIG. 3 shows a 3D view of a printed circuit board (PCB) wherein a plurality of resistors forms an L-shape;

FIG. 4 shows a first printed circuit board (PCB) unit variant and a second printed circuit board (PCB) unit variant of a product line; and

FIG. 5 shows a flow chart of a method for transmitting signals via differential communication lines with various PCB configurations according to the embodiments described herein.

### DETAILED DESCRIPTION

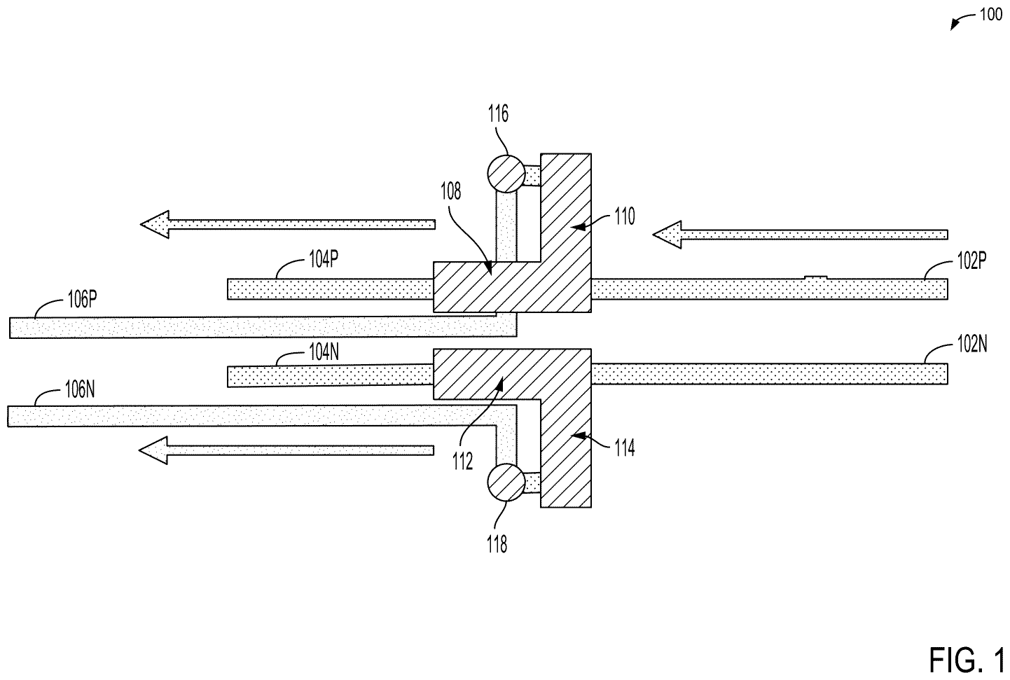

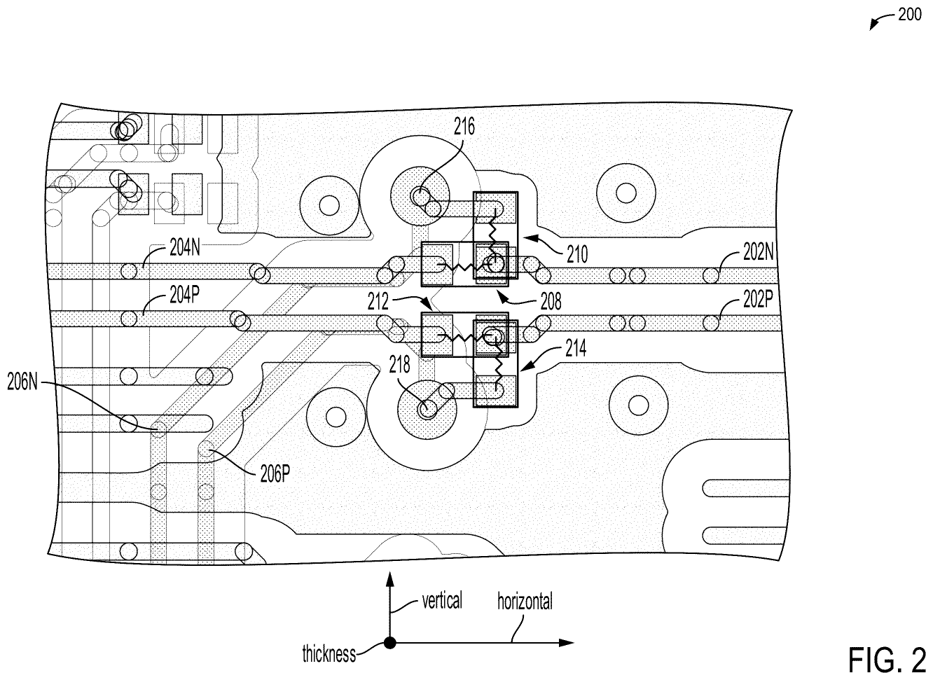

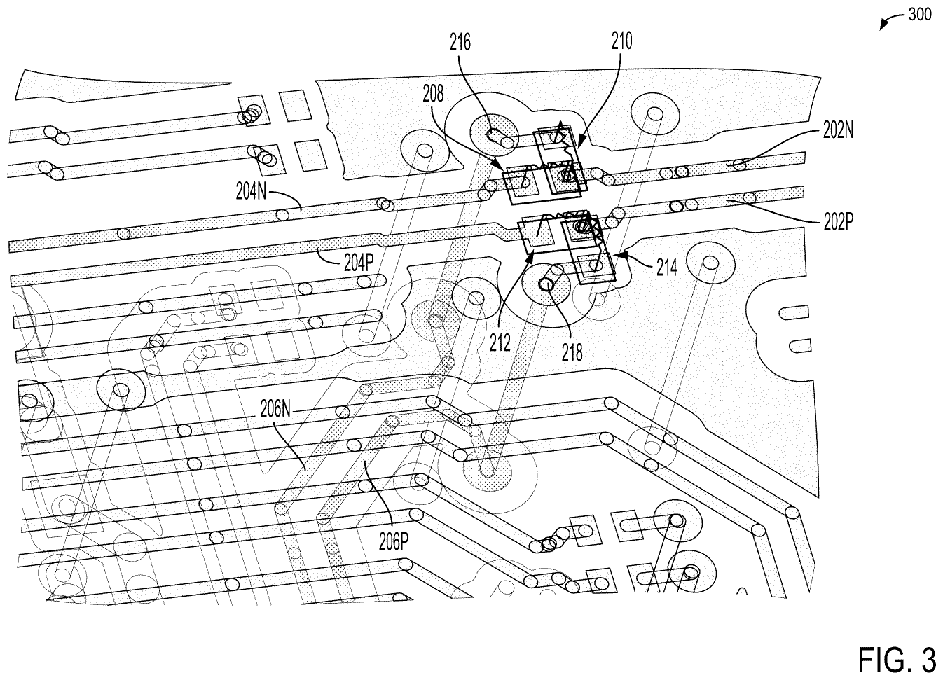

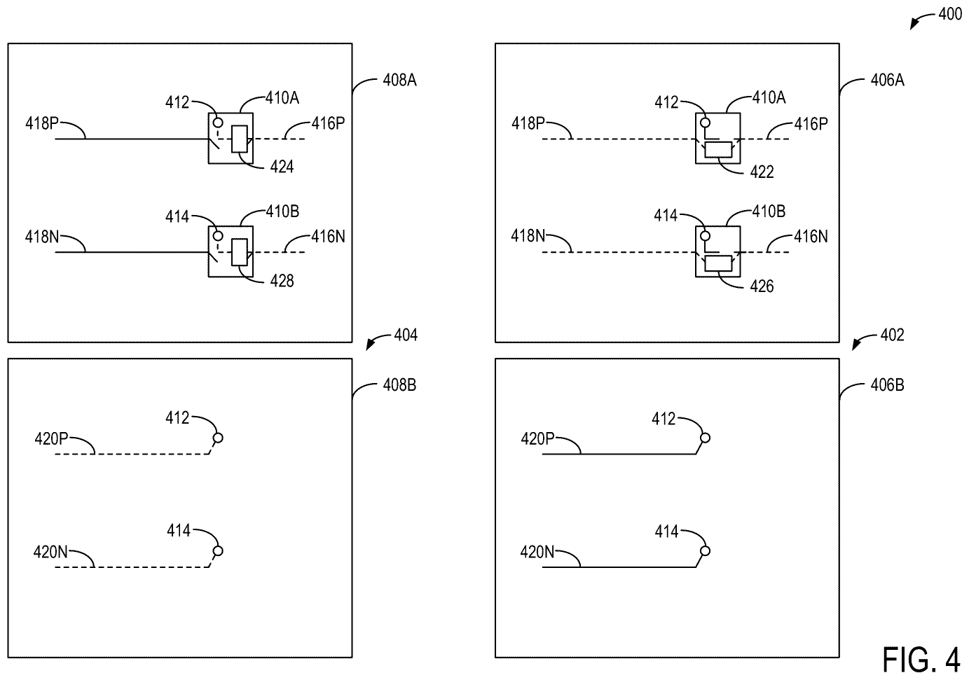

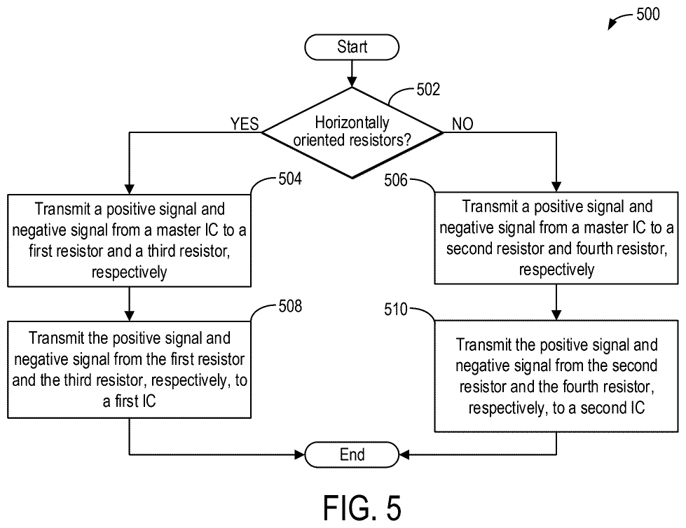

Disclosed herein are a system and method for routing differential communication lines to different integrated circuits based on printed circuit board (PCB) unit variants. An example of a printed circuit board (PCB) configuration wherein an L-shaped resistor configuration may be used for a first printed circuit board (PCB) unit variant and a second PCB unit variant is illustrated in FIG. 1. An example of a printed circuit board (PCB) with the L-shaped resistor configuration is illustrated FIG. 2 from a top view. As shown in FIG. 3, an example of a printed circuit board (PCB) with the L-shaped resistor configuration from a 3D view. FIG. 4 illustrates a first printed circuit board (PCB) unit variant and a second printed circuit board (PCB) unit variant of a product line. FIG. 5 illustrates a method for transmitting signals via differential communication lines for both of the first PCB unit variant and the second PCB unit variant.

FIG. 1 illustrates a simplified arrangement of a printed circuit board (PCB) configuration 100 for differential communication lines in a product line. The product line may include a first configuration of the PCB configuration 100 and a second configuration of the PCB configuration 100 of a plurality of configurations. The first configuration may be considered a first printed circuit board (PCB) unit variant and the second configuration may be considered a second printed circuit (PCB) unit variant of a plurality of printed circuit board (PCB) unit variants. The PCB configuration 100 may comprise a plurality of layers (e.g., multi-layered) wherein signals may be transmitted via a differential communication line from one layer in the plurality of layers to another layer in the plurality of layers, depending on a PCB layer stack selected. In particular, the PCB configuration 100 may comprise a first layer and an eighth layer in the plurality of layers.

Further, the PCB configuration 100 may further comprise a plurality of integrated circuits (IC), such as a master integrated circuit (IC), a first integrated circuit (IC), and a second integrated circuit (IC). As one example, the first PCB unit variant may include the master IC and the first IC. As another example, the second PCB unit variant may include the master IC and the second IC. Additionally, in other embodiments of the present disclosure, the first PCB unit variant may include the master IC and the second IC whereas the second PCB unit variant may include the master IC and the first IC. Other embodiments of the present disclosure may utilize additional or alternative PCB unit variants of the plurality of PCB unit variants and/or additional or alternative PCB configurations without departing from the scope of the disclosure described herein. For the purpose of this disclosure, the first PCB unit variant includes the master IC and the first IC and the second PCB unit variant includes the master IC and the second IC.

The PCB configuration 100 may include a first positive line portion 102P of differential communication line wherein positive signals from the master IC may be transmitted from the master IC to either the first IC or the second IC and a first negative line portion 102N of the differential communication line wherein negative signals from the master IC may be transmitted from the master IC to either the first IC or the second IC. In particular, a second positive line portion 104P of the differential communication line and a second negative line portion 104N of the differential communication line may transmit positive and negative signals, respectively, to the first IC. Additionally, a third positive line portion 106P of the differential communication line and a third negative line portion 106N of the differential communication line may transmit positive and negative signals, respectively, to the second IC. The second positive line portion 104P of the differential communication line and the second negative line portion 104N of the differential communication line may be located on the first layer of the plurality of layers of the PCB configuration 100. The third positive line portion 106P of differential communication line and the third negative line portion 106N of differential communication line may be located on the bottom layer of the plurality of layers of the PCB configuration 100.

The PCB configuration 100 may further include plurality of resistors, such as a first resistor 108, a second resistor 110, a third resistor 112, and a fourth resistor 114. Only one of the first resistor 108 and the second resistor 110 may be electrically coupled to first positive line portion 102P of the differential communication line. Similarly, one of the third resistor 112 and the fourth resistor 114 may be electrically coupled to a first negative line portion 102N of the differential communication line. The first resistor 108 and the second resistor 110 may not be electrically coupled to both the first positive line portion 102P of the differential communication line and the first negative line portion 102N of the differential communication line at the same time. Similarly, the third resistor 112 and the fourth resistor 114 may not be electrically coupled to the first positive line portion 102P of the differential communication line and the first negative line portion 102N of the differential communication line at the same time.

Either the first resistor 108 or the second resistor 110 may be mounted at a designated location of a first PCB unit variant at one time and either the first resistor 108 or the second resistor 110 may be mounted at a designated location of a second PCB unit variant at one time. Similarly, either the third resistor 112 or the fourth resistor 114 may be mounted at the designated location of the first PCB unit variant at one time and either the third resistor 112 or the fourth resistor 114 may be mounted at the designated location of the second PCB unit variant at one time. The designated location of the first PCB unit variant wherein either the first resistor 108 or the second resistor 110 may be received may be the same designated location of the first PCB unit variant wherein either the third resistor 112 or the fourth resistor 114 may be mounted.

In one embodiment, once the PCB configuration 100 is populated with the plurality of resistors in different positions at the designated location for the first PCB unit variant and the second PCB unit variant, different chip positioning utilizing the same differential communication line coming from a source may be enabled. In an example, the designated location for receiving either the first resistor 108 or the second resistor 110 is shaped such that, when populated with the first resistor 108 (and thus with the PCB in the first PCB unit variant), the first resistor 108 is in a first orientation, and when populated with the second resistor 110 (and thus with the PCB in the second PCB unit variant), the second resistor 110 is in a second orientation perpendicular to the first orientation.

The first resistor 108 may be received at the designated location of the first PCB unit variant or the second resistor 110 may be received at the designated location of the second PCB unit variant. In this way, the angle between the first resistor 108 and the second resistor 110 between the first PCB unit variant and the second PCB unit variant may vary by 90°, such that the first resistor 108 and the second resistor 110 would form an L-shape if both were mounted. As such, the first resistor 108 may be oriented horizontally in the first PCB unit variant whereas the second resistor 110 may be oriented vertically in the second PCB unit variant. It should be appreciated that the horizontal and vertical axis here are provided only for aiding the reader when looking at the drawings to identify relative directions of the PCB.

The designated location for mounting either the third resistor 112 or the fourth resistor 114 is shaped such that, when populated with the third resistor 112 (and thus with the PCB in the first PCB unit variant), the third resistor 112 is in the first orientation, and when populated with the fourth resistor 114 (and thus with the PCB in the second PCB unit variant), the fourth resistor 114 is in a second orientation perpendicular to the first orientation.

The third resistor 112 may be mounted at the designated location of the first PCB unit variant or the fourth resistor 114 may be received at the designated location of the second PCB unit variant. In this way, the angle between the third resistor 112 and the fourth resistor 114 between the first PCB unit variant and the second PCB unit variant may vary by 90°, such that the third resistor 112 and the fourth resistor 114 would form an L-shape if both were mounted. As such, the third resistor 112 may be oriented horizontally in the first PCB unit variant whereas the fourth resistor 114 may be oriented vertically in the second PCB unit variant. Further, the third resistor 112 and the fourth resistor 114 may be flipped vertically compared to the first resistor 108 and the second resistor 110 as illustrated herein.

Depending on the desired pathway of the positive signal and negative signal, the second resistor 110 may be oriented vertically to route the positive signal to the second IC path with a first via 116 positioned downstream from the second resistor 110 in the second PCB unit variant and the fourth resistor 114 may be oriented vertically to route the negative signal to the second IC path with a second via 118 positioned downstream from the fourth resistor 114 in the second PCB unit variant. The first via 116 may direct the positive signal from the first layer to the bottom layer of the plurality of layers of the PCB configuration 100 whereas the second via 118 may direct the negative signal from the first layer to the bottom layer of the plurality of layers of the PCB configuration 100. Additionally, the first resistor 108 may be oriented horizontally to route the positive signal to the first IC in the first PCB unit variant and the third resistor 112 may be oriented horizontally to route the negative signal to the first IC in the first PCB unit variant.

In this way, there will be no stub in the PCB configuration 100 created by remaining traces, bodies of the plurality of resistors, and the vias. In the first PCB unit variant, the positive and negative signals may be transmitted directly to the first IC via the respective second positive line portion 104P of the differential communication line and second negative line portion 104N of the differential communication line on the first layer of the plurality of layers of the PCB configuration 100. As described herein, the master IC, the horizontally oriented resistors (e.g., first resistor 108 and third resistor 112), and the first IC may be located on the first layer of PCB configuration 100 of the first PCB unit variant. Therefore, the PCB configuration 100 may not utilize a plurality of vias to transmit the positive and negative signals and may utilize a plurality of traces located on the first layer instead.

With regards to the second PCB unit variant, the positive signals may be transmitted indirectly to the second IC via the third positive line portion 106P of the differential communication line through the second resistor 110 and the first via 116, and the negative signals may be transmitted to the second IC through the third negative line portion 106N of differential communication line through the fourth resistor 114 and the second via 118 on the bottom layer of the plurality of layers of the PCB configuration 100. The first via and 116 and the second via 118 may extend from the first layer to the bottom layer. As described herein, the second IC and the vertically oriented resistors may be located on the bottom layer of PCB configuration of the second PCB unit variant. Therefore, the PCB configuration 100 does not include the trace and via stub since the first via 116 and the second via 118 extend from the first layer to the bottom layer

In some embodiments, the via stub may degrade signal parameters by introducing reflections that overlap with the original signal. By eliminating the via stub, the signal integrity may be maintained. It may be understood that in the present disclosure, the positive differential communication lines and the negative differential communication lines may not be capacitively coupled for short durations of time. However, the aforementioned disadvantage is compensated for by capacitively coupling the positive differential communication lines and negative differential communication lines with a ground plane of the PCB configuration 100. Additionally, electromagnetic interference may be reduced by implementing PCB configuration 100.

It may be understood that the examples provided are illustrative rather than absolute. Other embodiments of the present disclosure may include additional or alternative components or configurations than described herein without departing from the scope of the disclosure. As one example, the first resistor 108 and the second resistor described above may be utilized to route the negative signal of the first negative line portion 102N of the differential communication line instead of the positive signal of the first positive line portion 102P of the differential communication line. Similarly, the third resistor 112 and the fourth resistor 114 described above may be utilized to route the positive signal of the first positive line portion 102P of the differential communication line instead of the negative signal of the first negative line portion 102N of the differential communication line.

As illustrated in FIG. 2 and FIG. 3, a schematic, to-scale drawing, of a printed circuit board from a top view 200 and a 3D view 300 with greater complexity than described with respect to FIG. 1. The top view 200 and the 3D view 300 of the PCB may include various components, including a plurality of layers, a plurality of integrated circuits, a plurality of traces, a plurality of pads, and a plurality of vias as some examples. The top view 200 and the 3D view 300 of the PCB may further include a plurality of resistors and a plurality of configurations for a product line. The first configuration may be considered a first printed circuit board (PCB) unit variant and the second configuration may be considered a second printed circuit (PCB) unit variant of a plurality of printed circuit board (PCB) unit variants.

As one example, the first PCB unit variant may include a master integrated circuit (IC) and a first integrated circuit (IC). As another example, the second PCB unit variant may include the master IC and a second integrated circuit (IC). Additionally, in other embodiments of the present disclosure, the first PCB unit variant may include the master IC and the second IC whereas the second PCB unit variant may include the master IC and the first IC. Other embodiments of the present disclosure may utilize additional or alternative PCB unit variants of the plurality of PCB unit variants and/or additional or alternative PCB configurations without departing from the scope of the disclosure described herein. For the purpose of this disclosure, the first PCB unit variant includes the master IC and the first IC and the second PCB unit variant includes the master IC and the second IC.

The PCB in the top view 200 and the 3D view 300 may include the plurality of traces, such as a first negative trace 202N, a first positive trace 202P, a second negative trace 204N, a second positive trace 204P, a third negative trace 206N, and a third positive trace 206P. The first negative trace 202N and first positive trace 202P may be electrically routed to a master integrated circuit (IC) of the plurality of integrated circuits. The second negative trace 204N and the second positive trace 204P may be electrically coupled to a first integrated circuit (IC) of the first PCB unit variant whereas the third negative trace 206N and the third positive trace 206P may be electrically coupled to a second integrated circuit (IC) of the second PCB unit variant.

The first negative trace 202N may operate as a negative differential communication line that transmits negative signals whereas the first positive trace 202P may operate as a positive differential communication line that transmits positive signals. The second negative trace 204N may operate as a negative differential communication line that transmits inverted signals with respect to the positive line whereas the second positive trace 204P may operate as a positive differential communication line that transmits positive signals with respect to the negative line. The third negative trace 206N may operate as a negative differential communication line that transmits inverted signals whereas the third positive trace 206P may operate as a positive differential communication line that transmits positive signals with respect to the negative line. The first negative trace 202N, the second negative trace 204N, and the third negative trace 206N may be electrically coupled to a set of the plurality of resistors whereas the first positive trace 202P, the second positive trace 204P, and the third positive trace 206P may be electrically coupled to another set of the plurality of resistors

The first resistor 208 may be mounted at the same designated location of the PCB in the first PCB unit variant and the second resistor 210 may be mounted at the same designated location of the PCB in the second PCB unit variant. The third resistor 212 may be mounted at the same designated location of the PCB in the first PCB unit variant and fourth resistor 214 may be mounted at the same designated location of the PCB in the second PCB unit variant. In some embodiments, the designated locations for the first resistor 208 and a second resistor 210, and a third resistor 212 and a fourth resistor 214 may be located at designated pads of the plurality of pads. Further, each designated location includes a single input trace and two output traces, such that each designated location is populated with only one of a first resistor 208 and second resistor 210, and only one of the third resistor 212 and fourth resistor 214, the completed signal lines do not have any stubs branching therefrom. In this way, extraneous traces and/or vias with dead end are eliminated, thereby reducing an antenna effect of such extraneous traces, thus maintaining signal quality of the differential communication line, even at very high communication speeds (e.g., gigahertz).

The plurality of resistors, first via 216, and second via 218 may be configured according to the printed circuit board (PCB) configuration described in FIG. 1. As such, negative signals and positive signals originating from the master integrated circuit may be transmitted to either the first integrated circuit (IC) in the first PCB unit variant or second integrated circuit (IC) in the second PCB unit variant.

In particular, negative signals may be transmitted to the first resistor 208 and the second resistor 210 via the first negative trace 202N and the positive signals may be directed to the third resistor 212 and the fourth resistor 214 via the first positive trace 202P. Depending on the desired pathway of the embodiment, negative signals and positive signals may be transmitted to the second integrated circuit (IC) via vertically oriented resistors (e.g., second resistor 210 and fourth resistor 214) of the second PCB unit variant or to the first integrated circuit (IC) via horizontally oriented resistors (e.g., the first resistor 208 and the third resistor 212) of the first PCB unit variant.

It may be understood that the examples provided are illustrative rather than absolute. Other embodiments of the present disclosure may include additional or alternative components or configurations than described herein without departing from the scope of the disclosure. As one example, the first resistor 208 and the second resistor 210 described above and the third resistor 212 and the fourth resistor 214 can route either positive or negative signals inside a differential pair.

Turning to FIG. 3, the 3D view 300 illustrates the first layer relative to the plurality of layers contained by the PCB with regards to the plurality of traces, plurality of vias, and plurality of integrated circuits. The first negative trace 202N, the first positive trace 202P, the second negative trace 204N, and the second positive trace 204P may be located on a first layer of the plurality of layers of the PCB whereas the third negative trace 206N and the third positive trace 206P may be located on the bottom layer of the plurality of layers of the PCB.

The first via 216 may direct the negative signals to the bottom layer of the plurality of layers of the PCB wherein the third negative trace 206N is located. The second via 218 may direct the positive signals to the bottom layer of the plurality of layers of the PCB wherein the third positive trace 206P is located. In this way, the negative signals and positive signals may be transmitted to the second IC via the third negative trace 206N and the third positive trace 206P. The second negative trace 204N may direct negative signals to the first IC located on the first layer of the plurality of layers of the PCB whereas the second positive trace 204P may direct positive signals to the first IC on the first layer of the plurality of layers of the PCB.

In this way, there may be no via stub in the PCB. In the first PCB unit variant, the positive and negative signals may be transmitted directly to the first IC via the second positive trace 204P and second negative trace 204N on the first layer of the plurality of layers of the PCB. As described herein, the master IC, the horizontally oriented resistors, and the first IC may be located on the first layer of PCB of the first PCB unit variant. Therefore, the PCB may not utilize a plurality of vias to transmit the positive and negative signals and may utilize a plurality of traces located on the first layer instead.

With regards to the second PCB unit variant, the positive signals may be transmitted indirectly to the second IC via the third positive trace 206P via the first via 216 and the negative signals may be transmitted to the second IC via the third negative trace 206N via the second via 218 on the bottom/last layer of the plurality of layers of the PCB. The first via 216 and the second via 218 may extend from the first layer to the bottom layer. As described herein, the second IC and the vertically oriented resistors may be located on the bottom/last layer of PCB configuration of the second PCB unit variant. Therefore, the PCB may not include the via stub since the via extends from the first layer to the bottom layer.

In some embodiments, the via stub and the traces that remain unused may degrade signal parameters by introducing reflections that overlap with the original signal. By eliminating the via stub, the signal integrity may be maintained. It may be understood that in the present disclosure, the traces may not be capacitively coupled for short durations of time. However, the aforementioned disadvantage is compensated for by capacitively coupling the traces to a ground plane of the PCB. Additionally, electromagnetic interference may be reduced by implementing the disclosed configuration.

As shown in FIG. 4, a first printed circuit board (PCB) unit variant 402 and a second printed circuit board (PCB) unit variant 404 of a product line 400 according to the systems and methods described in FIGS. 1-3. The first PCB unit variant 402 may be a first configuration of the product line 400 whereas the second PCB unit variant 404 may be a second configuration of the product line 400. The first PCB unit variant 402 and the second PCB unit variant 404 include a plurality of traces, wherein traces transmitting a signal are represented by dashed lines and traces not transmitting a signal are represented by solid lines, a first designated location 410A, a second designated location 410B, a first via 412, and a second via 414. The plurality of traces may include a first positive trace 416P, a first negative trace 416N, a second positive trace 418P, a second negative trace 418N, a third positive trace 420P, and a third negative trace 420N. As illustrated herein, the first PCB unit variant 402 and the second PCB unit variant 404 include the same components, such as the first positive trace 416P, the first negative trace 416N, the second positive trace 418P, the second negative trace 418N, the third positive trace 420P, the third negative trace 420N, the first via 412, and the second via 414. In this way, the first PCB unit variant 402 and the second PCB unit variant 404 include the same set of traces and vias.

The first positive trace 416P and the second positive trace 418P may transmit positive signals from a master integrated circuit (IC) to a first integrated circuit (IC). The first positive trace 416P and the third positive trace 420P may transmit positive signals from a master integrated circuit (IC) to a second integrated circuit (IC). The first negative trace 416N and the second negative trace 418N may transmit negative signals from a master integrated circuit (IC) to a first integrated circuit (IC). The first negative trace 416N and the third negative trace 420N may transmit negative signals from a master integrated circuit (IC) to a second integrated circuit (IC).

The first PCB unit variant 402 includes a first layer 406A wherein the first IC is located and a bottom layer 406B wherein the second IC is located. The first layer 406A may include horizontally oriented resistors, such as a first resistor 422 and a third resistor 426. The horizontally oriented resistors may comprise a first orientation of populated resistors. Based on the configuration of the first resistor 422 and the third resistor 426, positive and negative signals are transmitted from the master IC via the first positive trace 416P and first negative trace 416N to the first IC via second positive trace 418P and second negative trace 418N after the encountering the first resistor 422 and third resistor 426.

The second PCB unit variant 404 includes a first layer 408A wherein the first IC is located and a bottom layer 408B wherein the second IC is located. The first layer 408A layer may include vertically oriented resistors, such as a second resistor 424 and a fourth resistor 428. The vertically oriented resistors may comprise a second orientation of populated resistors. Based on the configuration of the second resistor 424 and the fourth resistor 428, positive and negative signals are transmitted from the master IC via the first positive trace 416P and first negative trace 416N to the second IC via the third positive trace 420P and third negative trace 420N after the encountering the second resistor 424, the fourth resistor 428, the first via 412, and the second via 414. The first via 412 transmits positive signals originating from the first layer to the bottom layer of the second PCB unit variant 404 whereas the first via 414 transmits negative signals originating from the first layer to the bottom layer of the second PCB unit variant 404.

As described herein, other embodiments of the present disclosure may include additional or alternative components and configurations without departing from the scope of the disclosure. Other embodiments may deviate from the examples provided herein. For example, the second IC may be located on the first layers (e.g., 406A or 408A) and the first IC may be located on the bottom layer (e.g., 406B and 408B) of the first PCB unit variant and the second PCB unit variant.

FIG. 5 provides an example method for transmitting signals via differential communication lines using a first printed circuit board (PCB) unit variant and a second PCB unit variant of plurality of PCB unit variants. The method 500 will be described with regard to the system and components shown in FIGS. 1-4, although it may be understood that the method 500 may be implemented with other systems and components without departing from the scope of this disclosure. In particular, the method 500 will be described with respect to the first PCB unit variant and the second PCB unit variant. More specifically, for the first PCB unit variant, the method 500 includes routing a signal from a source to a first integrated circuit (IC) with a first pair of resistors, the first pair of resistors comprising a first resistor and a third resistor that are horizontally oriented. For the second PCB unit variant, the method 500 includes routing the signal from the source to a second IC with a second pair of resistors, the second pair of resistors comprising a second resistor and a fourth resistor being vertically oriented. In this way, signal integrity may be maintained by utilizing PCB unit variants without stubs and unused traces. The method 500 may be implemented as executable instructions in memory of a computing device, such as at least one controller of a plurality of controllers used to transmit signals via the differential communication lines.

At 502, the method 500 includes determining whether a PCB configuration includes horizontally oriented resistors. As described herein, a first PCB configuration may be a first PCB unit variant of a plurality of PCB unit variants, the first PCB unit variant comprising the first resistor and the third resistor. The first resistor and the third resistor are horizontally oriented. The first PCB unit variant is configured to transmit a signal from the master IC to the first IC located on a first layer of the first PCB unit variant. A second PCB configuration may be a second PCB unit variant of the plurality of PCB unit variants, the second PCB unit variant comprising the second resistor and the fourth resistor. The second resistor and the fourth resistor are vertically oriented. The second PCB unit variant is configured to transmit a signal from the master IC to the second IC located on a bottom layer of the second PCB unit variant. In some embodiments, the executable instructions stored in executed in the controller communicatively coupled to the respective PCB unit variant may include code that recognizes the respective PCB unit variant as being either the first PCB unit variant or the second PCB unit variant.

In response to the PCB configuration including horizontally oriented resistors, the method 500 includes transmitting a positive signal and negative signal from a master integrated circuit (IC) to a first resistor and a third resistor, respectively at 504. The positive signal may be directly transmitted to the first resistor located on the first layer via a first positive trace whereas the negative signal may be directly transmitted to the third resistor located on the first layer via a first negative trace

At 508, the method 500 includes transmitting the positive signal and negative signal from the first resistor and the third resistor, respectively, to a first IC. The positive signal may be directly transmitted to the first IC on the first layer from the first resistor via a second positive trace and the negative signal may be directly transmitted to the first IC from the third resistor via a second negative trace. The method 500 then ends.

In response to the PCB configuration including vertically oriented resistors, the method 500 includes transmitting a positive signal and negative signal from the master IC to a second resistor and a fourth resistor, respectively at 506. The positive signal may be indirectly transmitted to the second resistor located on the bottom layer via the first positive trace whereas the negative signal may be indirectly transmitted to the fourth resistor located on the bottom layer via the first negative trace. In particular, a first via directs the positive signal from the master IC to the second resistor and a second via directs the negative signal from the master IC to the fourth resistor.

At 510, the method 500 includes transmitting the positive signal and negative signal from the second resistor and the fourth resistor, respectively, to a second IC. The positive signal may be directly transmitted to the second IC on the bottom layer from the second resistor via a third positive trace and the negative signal may be directly transmitted to the second IC from the fourth resistor via a third negative trace. The method 500 then ends.

The technical effect of routing differential communication lines to different integrated circuits based on printed circuit board (PCB) unit variant includes eliminating a via stub and unused traces to reduce degradation of signal parameters in high-speed differential communication lines.

The disclosure also provides support for a system for a printed circuit board (PCB), comprising: a location for mounting either of a first resistor or a second resistor and another location for mounting either of a third resistor or fourth resistor, the location for receiving either the first resistor or the second resistor being shaped such that, when populated with the first resistor, the first resistor is in a first orientation, and when populated with the second resistor, the second resistor is in a second orientation perpendicular to the first orientation. In a first example of the system, the location for receiving either the third resistor or the fourth resistor being shaped such that, when populated with the third resistor, the third resistor is in the first orientation, and when populated with the fourth resistor, the fourth resistor is in the second orientation perpendicular to the first orientation.

In a second example of the system, optionally including the first example, the PCB is in a first configuration when populated with the first resistor and the third resistor and the PCB is in a second configuration when populated with the second resistor and the fourth resistor. In a third example of the system, optionally including one or both of the first and second examples, in each of the first configuration and the second configuration, the location includes only a single input trace, and two output traces and population of the location by one of the first resistor and the second resistor ensures completed signal lines do not have stubs branching therefrom. In a fourth example of the system, optionally including one or more or each of the first through third examples, in each of the first configuration and the second configuration, the location includes only the single output trace, and two output traces and population of the location by one of the third resistor and the fourth resistor ensures completed signal lines do not have stubs branching therefrom.

In a fifth example of the system, optionally including one or more or each of the first through fourth examples, the first configuration is a first PCB unit variant and the second configuration is a second PCB unit variant of a plurality of PCB unit variants. In a sixth example of the system, optionally including one or more or each of the first through fifth examples, each of the first configuration and the second configuration comprise a plurality of layers. In a seventh example of the system, optionally including one or more or each of the first through sixth examples, for the second configuration, signals are transmitted via a differential communication line from one layer in the plurality of layers to another layer in the plurality of layers.

The disclosure also provides support for a system for a printed circuit board (PCB), comprising: a first PCB unit variant of a plurality of PCB unit variants comprising a first resistor mounted at a designated location, a third resistor mounted at another designated location, a first via, a second via, and a master integrated circuit (IC), the first resistor and the third resistor being oriented horizontally to route a signal to a first IC, and a second PCB unit variant of the plurality of PCB unit variants comprising a second resistor at the designated location, a fourth resistor mounted at the other designated location, the first via, the second via, and the master IC, the second resistor and the fourth resistor being oriented vertically to route the signal to a second IC.

In a first example of the system, the first PCB unit variant and the second PCB unit variant further comprises a first positive line portion of a differential communication line to transmit positive signals from the master IC to either the first IC or the second IC and a first negative line portion of the differential communication line to transmit negative signals from the master IC to either the first IC or the second IC. In a second example of the system, optionally including the first example, the first PCB unit variant further comprises a second positive line portion of the differential communication line and a second negative line portion of the differential communication line transmits positive signals and negative signals, respectively, to the first IC. In a third example of the system, optionally including one or both of the first and second examples, the first PCB unit variant further comprises a third positive line portion of the differential communication line and a third negative line portion of the differential communication line transmits positive signals and negative signals, respectively, to the second IC.

In a fourth example of the system, optionally including one or more or each of the first through third examples, only one of the first resistor and the second resistor is electrically coupled to the first positive line portion of the differential communication line and only one of the third resistor and the fourth resistor is electrically to the first negative line portion of the differential communication line. In a fifth example of the system, optionally including one or more or each of the first through fourth examples, the first PCB unit variant and the second PCB unit variant further comprise a plurality of layers wherein the master IC, the first positive line portion, the first negative line portion, the first resistor, the third resistor, the first IC, the second positive line portion, and the second negative line portion are located on a first layer of the plurality of layers and the second resistor, the fourth resistor, the second IC, the third positive line portion, and the third negative line portion are located on a bottom layer of the plurality of layers. In a sixth example of the system, optionally including one or more or each of the first through fifth examples, the first via and the second via extend from the first layer to the bottom layer. In a seventh example of the system, optionally including one or more or each of the first through sixth examples, the first positive line portion is a first positive trace, the first negative line portion is a first negative trace, the second positive line portion is a second positive trace, the second negative line is a second negative trace, the third positive line portion is a third positive trace, and the third negative line portion is a third negative trace.

The disclosure also provides support for a method for transmitting signals via differential communication lines, comprising: for a first printed circuit board (PCB) unit variant, routing a signal from a source to a first integrated circuit (IC) with a first pair of resistors, the first pair of resistors comprising a first resistor and a third resistor that are horizontally oriented, and for a second PCB unit variant, routing the signal from the source to a second IC with a second pair of resistors, the second pair of resistors comprising a second resistor and a fourth resistor being vertically oriented. In a first example of the method, routing the signal from the source to the first IC with the first pair of resistors comprises: transmitting a positive signal from a master IC to the first resistor via a first positive trace and a negative signal from the master IC to the third resistor via a first negative trace, and transmitting the positive signal received from the first resistor to the first IC via a second positive trace and the negative signal received from the third resistor to the first IC via a second negative trace.

In a second example of the method, optionally including the first example, routing the signal from the source to the second IC with the second pair of resistors comprises: transmitting a positive signal from a master IC to the second resistor via the first positive trace and a negative signal from the master IC to the fourth resistor via the first negative trace, and transmitting the positive signal received from the second resistor to the second IC via a third positive trace and the negative signal received from the fourth resistor to the second IC via a third negative trace. In a third example of the method, optionally including one or both of the first and second examples, a first via directs the positive signal from the master IC to the second resistor and a second via directs the negative signal from the master IC to the fourth resistor.

As used herein, an element or step recited in the singular and preceded with the word “a” or “an” should be understood as not excluding plural of said elements or steps, unless such exclusion is stated. Furthermore, references to “one embodiment” or “one example” of the present disclosure are not intended to be interpreted as excluding the existence of additional embodiments that also incorporate the recited features.

As used herein, terminology in which “an embodiment,” “some embodiments,” or “various embodiments” are referenced signify that the associated features, structures, or characteristics being described are in at least some embodiments, but are not necessarily in all embodiments. Moreover, the various appearances of such terminology do not necessarily all refer to the same embodiments, and are not intended to be interpreted as excluding the existence of additional embodiments that also incorporate the recited features.

As used herein, terminology in which elements are presented in a list using “and/or” language means any combination of the listed elements. For example, “A, B, and/or C” may mean any of the following: A alone; B alone; C alone; A and B; A and C; B and C; or A, B, and C. As used herein, the term “substantially similar to” is construed to mean the same as with a tolerance for variation that a person of ordinary skill in the art would recognize as being reasonable. As used herein, terms such as “first,” “second,” “third,” and so on are used merely as labels, and are not intended to impose numerical requirements or a particular positional order on their objects.

1. A system for a printed circuit board (PCB), comprising:
a location for mounting either of a first resistor or a second resistor and another location for mounting either of a third resistor or a fourth resistor, the location for receiving either the first resistor or the second resistor being shaped such that, when populated with the first resistor, the first resistor is in a first orientation, and when populated with the second resistor, the second resistor is in a second orientation perpendicular to the first orientation.

2. The system of claim 1, wherein the location for receiving either the third resistor or the fourth resistor being shaped such that, when populated with the third resistor, the third resistor is in the first orientation, and when populated with the fourth resistor, the fourth resistor is in the second orientation perpendicular to the first orientation.

3. The system of claim 1, wherein the PCB is in a first configuration when populated with the first resistor and the third resistor and the PCB is in a second configuration when populated with the second resistor and the fourth resistor.

4. The system of claim 3, wherein in each of the first configuration and the second configuration, the location includes only a single input trace, and two output traces and population of the location by one of the first resistor and the second resistor ensures completed signal lines do not have stubs branching therefrom.

5. The system of claim 3, wherein in each of the first configuration and the second configuration, the location includes only the single output trace, and two output traces and population of the location by one of the third resistor and the fourth resistor ensures completed signal lines do not have stubs branching therefrom.

6. The system of claim 3, wherein the first configuration is a first PCB unit variant and the second configuration is a second PCB unit variant of a plurality of PCB unit variants.

7. The system of claim 6, wherein each of the first configuration and the second configuration comprise a plurality of layers.

8. The system of claim 7, wherein for the second configuration, signals are transmitted via a differential communication line from one layer in the plurality of layers to another layer in the plurality of layers.

9. A system for a printed circuit board (PCB), comprising:
a first PCB unit variant of a plurality of PCB unit variants comprising a first resistor mounted at a designated location, a third resistor mounted at another designated location, a first via, a second via, and a master integrated circuit (IC), the first resistor and the third resistor being oriented horizontally to route a signal to a first IC; and
a second PCB unit variant of the plurality of PCB unit variants comprising a second resistor at the designated location, a fourth resistor mounted at the other designated location, the first via, the second via, and the master IC, the second resistor and the fourth resistor being oriented vertically to route the signal to a second IC.

10. The system of claim 9, wherein the first PCB unit variant and the second PCB unit variant further comprises a first positive line portion of a differential communication line to transmit positive signals from the master IC to either the first IC or the second IC and a first negative line portion of the differential communication line to transmit negative signals from the master IC to either the first IC or the second IC.

11. The system of claim 10, wherein the first PCB unit variant further comprises a second positive line portion of the differential communication line and a second negative line portion of the differential communication line transmits positive signals and negative signals, respectively, to the first IC.

12. The system of claim 10, wherein the first PCB unit variant further comprises a third positive line portion of the differential communication line and a third negative line portion of the differential communication line transmits positive signals and negative signals, respectively, to the second IC.

13. The system of claim 10, wherein only one of the first resistor and the second resistor is electrically coupled to the first positive line portion of the differential communication line and only one of the third resistor and the fourth resistor is electrically to the first negative line portion of the differential communication line.

14. The system of claim 10, wherein the first PCB unit variant and the second PCB unit variant further comprise a plurality of layers wherein the master IC, the first positive line portion, the first negative line portion, the first resistor, the third resistor, the first IC, the second positive line portion, and the second negative line portion are located on a first layer of the plurality of layers and the second resistor, the fourth resistor, the second IC, the third positive line portion, and the third negative line portion are located on a bottom layer of the plurality of layers.

15. The system of claim 14, wherein the first via and the second via extend from the first layer to the bottom layer.

16. The system of claim 14, wherein the first positive line portion is a first positive trace, the first negative line portion is a first negative trace, the second positive line portion is a second positive trace, the second negative line is a second negative trace, the third positive line portion is a third positive trace, and the third negative line portion is a third negative trace.

17. A method for transmitting signals via differential communication lines, comprising:
for a first printed circuit board (PCB) unit variant, routing a signal from a source to a first integrated circuit (IC) with a first pair of resistors, the first pair of resistors comprising a first resistor and a third resistor that are horizontally oriented; and
for a second PCB unit variant, routing the signal from the source to a second IC with a second pair of resistors, the second pair of resistors comprising a second resistor and a fourth resistor being vertically oriented.

18. The method of claim 17, wherein routing the signal from the source to the first IC with the first pair of resistors comprises:
transmitting a positive signal from a master IC to the first resistor via a first positive trace and a negative signal from the master IC to the third resistor via a first negative trace; and
transmitting the positive signal received from the first resistor to the first IC via a second positive trace and the negative signal received from the third resistor to the first IC via a second negative trace.

19. The method of claim 17, wherein routing the signal from the source to the second IC with the second pair of resistors comprises:
transmitting a positive signal from a master IC to the second resistor via the first positive trace and a negative signal from the master IC to the fourth resistor via the first negative trace; and
transmitting the positive signal received from the second resistor to the second IC via a third positive trace and the negative signal received from the fourth resistor to the second IC via a third negative trace.

20. The method of claim 19, wherein a first via directs the positive signal from the master IC to the second resistor and a second via directs the negative signal from the master IC to the fourth resistor.
